(19) United States
(12) Patent Application Publication
(10) Pub. No.: US 2026/0153554 A1
(43) Pub. Date: Jun. 4, 2026

(54) PROBE CARD AND METHOD FOR INSPECTING LIGHT EMITTING DIODE USING THE SAME

(71) Applicant: LG Display Co., Ltd., Seoul (KR)

(72) Inventors: YongSeok Kwak, Paju-si (KR); Myungsoo Han, Goyang-si (KR); Il-Soo Kim, Goyang-si (KR)

(73) Assignee: LG Display Co., Ltd., Seoul (KR)

(21) Appl. No.: 19/362,322

(22) Filed: Oct. 17, 2025

(30) Foreign Application Priority Data
Dec. 2, 2024 (KR) 10-2024-0176326

(51) Int. Cl. G01R 31/26; G01R 1/073

(52) U.S. Cl. CPC G01R 31/2635; G01R 1/07307

(57) ABSTRACT

The present disclosure relates to a probe card and a method for inspecting a light emitting diode using the same. The probe card may include a probe substrate, a photodetector unit on the probe substrate, an electrode unit on the photodetector unit and including a first pin electrode and a second pin electrode, a penetration hole through the second pin electrode, the penetration hole overlapping the photodetector unit. Accordingly, the penetration hole is formed in the second pin electrode to allow the light emitted from the light emitting diode to be incident on the photodetector unit, and the electrode unit and the photodetector unit may simultaneously inspect the light emitting diode.

### CROSS-REFERENCE TO RELATED APPLICATION

This application claims the priority of Korean Patent Application No. 10-2024-0176326, filed on Dec. 2, 2024, in the Korean Intellectual Property Office, the disclosure of which is incorporated herein by reference.

### TECHNICAL FIELD

The present disclosure relates to a probe card and a method for inspecting a light emitting diode using the same, and more particularly to a probe card which simultaneously inspects an optical characteristic and an electrical characteristic of a light emitting diode (LED) and a method for inspecting a light emitting diode using the same.

### BACKGROUND

Display devices used for a monitor of a computer, a television, or a cellular phone include, among others, an organic light emitting display device (OLED), which is a self-emitting device, and a liquid crystal display device (LCD), which requires a separate light source.

As applications for display devices are becoming more diversified, for example, from personal digital assistants to monitors of computers and televisions, a display device with a large display area and reduced volume and weight is being studied.

Further, in recent years, a display device including a light emitting diode (LED) is attracting attention as a next generation display device. Since the LED is formed of an inorganic material, rather than an organic material, its reliability is excellent so that its lifespan is longer than that of the liquid crystal display device or the organic light emitting display device. Further, the LED has a relatively fast lighting speed, excellent luminous efficiency, and a strong impact resistance so that its stability is excellent, and an image having a high luminance can be displayed.

### SUMMARY

An object of the present disclosure is to provide a probe card which can simultaneously inspect the optical characteristic and the electrical characteristic of an entire light emitting diode array and a method for inspecting a light emitting diode using the same.

Another object of the present disclosure is to provide a probe card which can easily transmit light of a light emitting diode to a photodetector unit and a method for inspecting a light emitting diode using the same.

Yet another object of the present disclosure is to provide a probe card which can selectively pick up only a defective light emitting diode and a method for inspecting a light emitting diode using the same.

Still another object of the present disclosure is to provide a probe card which has an improved durability of a pin electrode and a method for inspecting a light emitting diode using the same. In some example embodiments, the above method may utilize the specific example structure of the probe card described in the detailed description.

Objects of the present disclosure are not limited to the above-mentioned objects, and other objects, which are not mentioned above, can be clearly understood by those skilled in the art from the following descriptions.

To achieve these objects and other advantages and in accordance with the purpose of the present disclosure, as embodied and broadly described herein, a probe card according to an aspect of the present disclosure includes a probe substrate, a photodetector unit on the probe substrate, an electrode unit on the photodetector unit and including a first pin electrode and a second pin electrode, a penetration hole through the second pin electrode, the penetration hole overlapping the photodetector unit. Accordingly, the penetration hole is formed in the second pin electrode to allow the light emitted from the light emitting diode to be incident on the photodetector unit, and the electrode unit and the photodetector unit may simultaneously inspect the light emitting diode.

According to another aspect of the present disclosure, a probe card for inspecting a light emitting diode array includes a probe substrate, a plurality of photodetector units on the probe substrate, and a plurality of electrode units, each on a corresponding one of the photodetector units and including a first pin electrode and a second pin electrode. The second pin electrode may include a hollow center overlapping the corresponding one of the photodetector units.

According to yet another aspect of the present disclosure, a method for inspecting a light emitting diode array including a plurality of light emitting diodes on a array substrate includes contacting the plurality of light emitting diodes respectively with the electrode units of the above-described probe card; inspecting an optical characteristic and an electrical characteristic of each of the plurality of light emitting diodes respectively with an adjacent one of the photodetector units and an adjacent one of the electrode units of the probe card to determine if any of the plurality of light emitting diodes is defective; and if a light emitting diode, among the plurality of light emitting diodes, is determined to be defective, picking up the defective light emitting diode with the probe card. Accordingly, only the defective light emitting diode may be selectively picked up and removed.

Other detailed matters of various example embodiments are included in the detailed description and the drawings.

According to an aspect of the present disclosure, the optical characteristic and the electrical characteristic of an entire light emitting diode array may be simultaneously inspected.

According to another aspect of the present disclosure, the light emitted by the light emitting diode can be easily transmitted to the photodetector unit.

According to yet another aspect of the present disclosure, after an inspection process of a plurality of light emitting diodes is completed, only a defective light emitting diode may be selectively picked up and removed.

According to still another aspect of the present disclosure, an elastic insulating layer enclosing the pin electrode may be formed to relieve an impact of the pin electrode and improve the durability of the pin electrode.

The effects according to the present disclosure are not limited to the contents exemplified above, and various additional effects may be attained from the present disclosure.

### BRIEF DESCRIPTION OF DRAWINGS

The above and other aspects, features, and other advantages of the present disclosure can be more clearly understood from the following detailed description taken in conjunction with the accompanying drawings, in which:

FIG. 1 is a diagram of an inspection system of a light emitting diode according to an example embodiment of the present disclosure;

FIGS. 2 and 3 are cross-sectional views of a light emitting diode array and a probe card according to an example embodiment of the present disclosure;

FIG. 4 is a schematic plan view of a probe card according to an example embodiment of the present disclosure; and

FIGS. 5A to 5H are process diagrams for explaining a manufacturing method of a probe card according to an example embodiment of the present disclosure.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein and can be implemented in various other forms. The example embodiments are provided by way of example only so that those skilled in the art can more fully understand the features and aspects of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure.

Such terms as “including,” “having,” and “consist of,” where used herein, are generally intended to allow other components to be added unless the terms are used with a more specific term like “only.” Any references to singular may include plural, and vice versa, unless expressly stated otherwise.

Components are to be interpreted to include an ordinary error range even if not expressly stated.

Where the position relation between two parts is described using such terms as “on,” “above,” “below,” and “next,” one or more parts may be positioned between the two parts unless the terms are used with a more specific term like “immediately” or “directly.”

Where an element or layer is described as being disposed “on” one other element or layer, the element or layer may be disposed directly on the one other element or layer, or an additional layer or element may be interposed therebetween.

Although terms like “first” and “second” may be used for describing various components, these components are not limited by these terms. These terms are merely used to refer to one component separately from the other components. Therefore, a first component mentioned below may be a second component, and vice versa, in a technical concept of the present disclosure.

Like reference numerals generally denote like elements throughout the disclosure unless otherwise specified.

A size and a thickness of each component illustrated in the drawing are illustrated for convenience of description, and the present disclosure is not limited to the size and the thickness of the component illustrated.

The features of various example embodiments of the present disclosure can be partially or entirely adhered to or combined with each other and can be interlocked and operated in technically various ways, and the example embodiments can be carried out independently of or in association with each other.

Hereinafter, example embodiments of the present disclosure will be described in detail with reference to accompanying drawings.

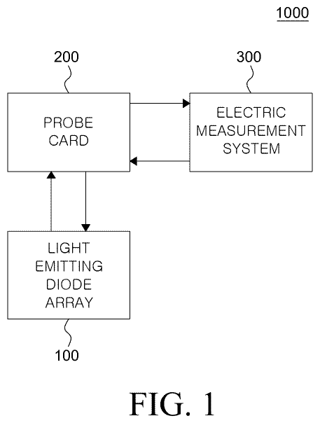

FIG. 1 is a diagram of an inspection system of a light emitting diode according to an example embodiment of the present disclosure.

As illustrated in FIG. 1, the inspection system 1000 is a system for inspecting an optical characteristic and an electrical characteristic of a light emitting diode 120. The inspection system 1000 includes a light emitting diode array 100, a probe card 200, and an electric measurement system 300.

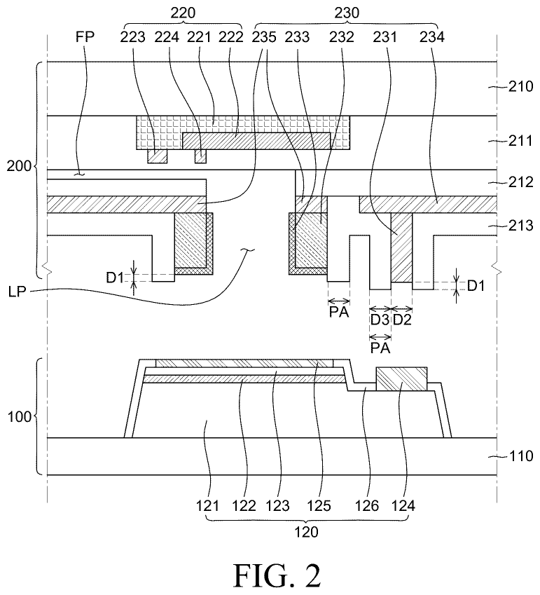

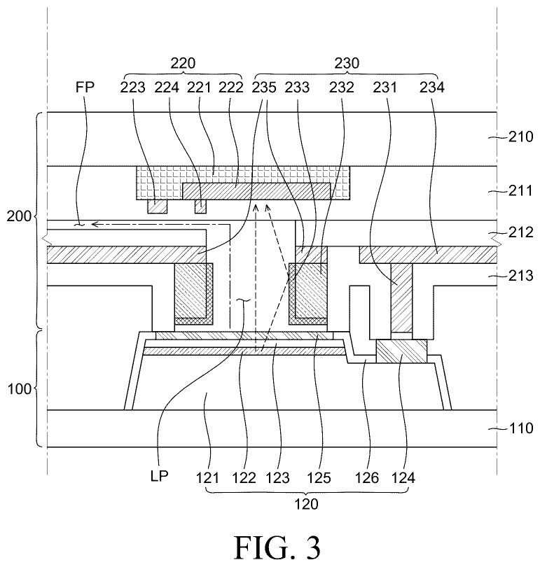

The light emitting diode array 100 includes a plurality of light emitting diodes 120 disposed on one substrate. For example, the light emitting diode array 100 may be a plurality of light emitting diodes 120 (see, e.g., FIGS. 2 and 3) which is disposed on one wafer or one donor.

The probe card 200 is an inspection device for inspecting the optical characteristic and the electrical characteristic of the plurality of light emitting diodes 120. The probe card 200 may apply a signal to each of the plurality of light emitting diodes 120 of the light emitting diode array 100 and may detect a signal output from the plurality of light emitting diodes 120. The probe card 200 may connect a pin electrode to the plurality of light emitting diodes 120 to inspect an electrical characteristic. Further, the probe card 200 may receive the light emitted from the plurality of light emitting diodes 120 to inspect the optical characteristic of the light emitting diodes 120. When a defective light emitting diode 120 is detected, the probe card 200 may pick up and remove the defective light emitting diode.

The electric measurement system 300 is a system that can apply a driving signal to the probe card 200 and determine a defect in a light emitting diode 120 based on information measured by the probe card 200. The electric measurement system 300 is connected to the probe card 200 to inspect the electrical characteristic and the optical characteristic of the light emitting diode 120. For example, the electric measurement system 300 applies a voltage to the pin electrode of the probe card 200 or receives information of the light emitting diode 120 measured by the probe card 200 to analyze characteristics of the light emitting diode 120. The electric measurement system 300 identifies electrical characteristics of the light emitting diode 120, for example, response or leakage current, to determine a short-circuit or an open failure in the light emitting diode 120. The electric measurement system 300 may determine whether the light emitting diode 120 emits light from the light received from the probe card 200.

Hereinafter, the light emitting diode array 100 and the probe card 200 will be described in detail with reference to FIGS. 2 to 4.

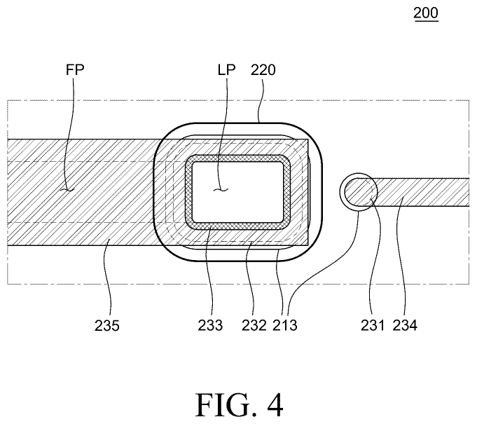

FIGS. 2 and 3 are cross-sectional views of a light emitting diode array and a probe card according to an example embodiment of the present disclosure. FIG. 4 is a schematic plan view of a probe card according to an example embodiment of the present disclosure. In FIGS. 2 and 3, for the convenience of description, only one light emitting diode 120, among the plurality of light emitting diodes 120 of the light emitting diode array 100, one photodetector unit 220, among the plurality of photodetector units 220, and one electrode unit 230, among the plurality of electrode units 230, are illustrated.

As shown in FIGS. 2 to 4, the light emitting diode array 100 includes an array substrate 110 and a plurality of light emitting diodes 120.

On the array substrate 110, the plurality of light emitting diodes 120 are disposed. The array substrate 110 may be a wafer on which the light emitting diodes 120 are grown or a donor to which the light emitting diodes 120 are temporarily transferred. The plurality of light emitting diodes 120 on the array substrate 110 may be transferred to another place, substrate, or device to be used after the inspection process is completed.

The plurality of light emitting diodes 120 are disposed on the array substrate 110. The plurality of light emitting diodes 120 are semiconductor elements which emit light in an array when applied with a current. The light emitting diode 120 may be any one of a light-emitting diode (LED) or a micro light-emitting diode (micro LED), but the example embodiments of the present disclosure are not limited thereto.

Each of the plurality of light emitting diodes 120 includes a first semiconductor layer 121, an emission layer 122, a second semiconductor layer 123, a first electrode 124, a second electrode 125, and a protection film 126.

The first semiconductor layer 121 is disposed on the array substrate 110, and the second semiconductor layer 123 is disposed on the first semiconductor layer 121. Any one of the first semiconductor layer 121 and the second semiconductor layer 123 may be a semiconductor layer doped with an n-type impurity, and the other may be a semiconductor layer doped with a p-type impurity. For example, the first semiconductor layer 121 and the second semiconductor layer 123 may be semiconductor layers doped with n-type or p-type impurities into a host material, such as gallium nitride (GaN), indium aluminum phosphide (InAlP), or gallium arsenide (GaAs).

The emission layer 122 is disposed between the first semiconductor layer 121 and the second semiconductor layer 123. The emission layer 122 may emit light based on a driving current supplied to the light emitting diode 120. For example, the emission layer 122 may be formed by a single layer or a multi-quantum well (MQW) structure, and for example, may be formed of indium gallium nitride (InGaN) or gallium nitride (GaN), but is not limited thereto.

The first electrode 124 is disposed on a top surface of the first semiconductor layer 121, and the second electrode 125 is disposed on a top surface of the second semiconductor layer 123. Voltages are applied respectively to the first electrode 124 and the second electrode 125 to drive the light emitting diode 120.

The protection film 126 is disposed so as to enclose the first semiconductor layer 121, the emission layer 122, and the second semiconductor layer 123. The protection film 126 is an insulating film which is disposed so as to enclose at least a part of the first semiconductor layer 121, the emission layer 122, and the second semiconductor layer 123 to suppress the short-circuit defect.

The probe card 200 is an inspection device which can inspect the optical characteristic and the electrical characteristic of the plurality of light emitting diodes 120. The probe card 200 includes a probe substrate 210, a first insulating layer 211, a second insulating layer 212, a third insulating layer 213, a photodetector unit 220, and an electrode unit 230.

First, the probe substrate 210 supports other configurations or elements of the probe card 200. The plurality of photodetector units 220 and the plurality of electrode units 230 may be formed on the probe substrate 210 to form the probe card 200.

The plurality of photodetector units 220 are disposed on one surface of the probe substrate 210. A photodetector unit 220 is provided to inspect the optical characteristic and to receive the light emitted by a light emitting diode 120 to convert the received light into an electric energy. The electric measurement system 300 senses the electric energy converted in the photodetector unit 220 to detect whether the light emitting diode 120 emits light. Further, among the light emitting diodes 120 which satisfy the electrical characteristic, there may be a light emitting diode 120 which fails to emit light, and the photodetector unit 220 which is positioned to directly sense light from that light emitting diode 120 may more accurately detect the defective light emitting diode 120.

The photodetector unit 220 includes an N-type semiconductor layer 221, a P-type semiconductor layer 222, an N-type electrode 223, and a P-type electrode 224.

The N-type semiconductor layer 221 is disposed on one surface of the probe substrate 210, and the P-type semiconductor layer 222 is disposed on one surface of the N-type semiconductor layer 221. The N-type semiconductor layer 221 is a semiconductor layer doped with an n-type impurity, and the P-type semiconductor layer 222 is a semiconductor layer doped with a p-type impurity. For example, the N-type semiconductor layer 221 may be formed of silicon (Si) doped with an n-type impurity, and the P-type semiconductor layer 222 may be formed of silicon (Si) or germanium (Ge) including a p-type impurity. The N-type semiconductor layer 221 and the P-type semiconductor layer 222 may form a PN junction, and in the PN junction, electrons and holes may be generated by the incident light to flow a current.

The N-type electrode 223 is disposed on one surface of the N-type semiconductor layer 221, and the P-type electrode 224 is disposed on one surface of the P-type semiconductor layer 222. The N-type electrode 223 and the P-type electrode 224 are electrodes which can transmit a current generated in the PN junction to the electric measurement system 300. The N-type electrode 223 and the P-type electrode 224 are electrically connected to the electric measurement system 300 to transmit current generated in the photodetector unit 220.

Next, the first insulating layer 211 is disposed on one surface of the probe substrate 210 and covers the photodetector unit 220. The first insulating layer 211 is disposed so as to cover the photodetector unit 220 to protect the photodetector unit 220.

The second insulating layer 212 is disposed on one surface of the first insulating layer 211, and a suction hole FP may be formed along an interface between the second insulating layer 212 and the first insulating layer 211. The suction hole FP is provided to pick up the light emitting diode 120 by a vacuum suction method and may be formed by passing through the second insulating layer 212. The suction hole FP may be connected to a penetration hole LP. For example, the suction hole FP may be connected to a vacuum suction device (not illustrated), and as represented by an arrow illustrated with a one-dot chain line of FIG. 3, the vacuum suction device connected to the suction hole FP may suck air to pick up the light emitting diode 120.

The electrode unit 230 is disposed on the second insulating layer 212. The electrode unit 230 can detect the electrical characteristic of the light emitting diode 120 and is configured to apply a voltage to the light emitting diode 120. The electrode unit 230 includes a first pin electrode 231, a second pin electrode 232, a first wiring line 234, a second wiring line 235, and a reflection layer 233.

The first wiring line 234 and the second wiring line 235 are disposed on one surface of the second insulating layer 212. The first wiring line 234 is connected to the first pin electrode 231, and the second wiring line 235 is connected to the second pin electrode 232. The first wiring line 234 and the second wiring line 235 are connected to the electric measurement system 300 to transmit voltages respectively to the first pin electrode 231 and the second pin electrode 232.

The first pin electrode 231 is disposed on the first wiring line 234, and the second pin electrode 232 is disposed on one surface of the second wiring line 235. The first pin electrode 231 and the second pin electrode 232 can apply a voltage to the light emitting diode 120. When the probe card 200 is in contact with the light emitting diode array 100, the first pin electrode 231 may be in contact with the first electrode 124 of the light emitting diode 120, and the second pin electrode 232 may be in contact with the second electrode 125 of the light emitting diode 120. Accordingly, a voltage can be applied between the first electrode 124 and the second electrode 125 of the light emitting diode 120 using the first pin electrode 231 and the second pin electrode 232 to allow the light emitting diode 120 to emit light.

The first pin electrode 231 may be a pin-shaped electrode, and the second pin electrode 232 may be a hollow pin-shaped electrode in which the penetration hole LP is formed. The first pin electrode 231 and the second pin electrode 232 may have diameters corresponding to the first electrode 124 and the second electrode 125 of the light emitting diode 120, respectively. For example, the first electrode 124 of the light emitting diode 120 may be smaller than the second electrode 125, and the first pin electrode 231 may be formed to have a diameter smaller than that of the second pin electrode 232.

In another aspect, the second pin electrode 232, which is to be in contact with the second electrode 125 of the light emitting diode 120, and a part of the second wiring line 235 connected to the second pin electrode 232 may overlap the second electrode 125 and the emission layer 122 below the second electrode 125. Therefore, most of the light emitted from the emission layer 122 may travel toward the second pin electrode 232, and the photodetector unit 220 may overlap the emission layer 122 and the second pin electrode 232 on the emission layer 122 to sense the light emitted by the light emitting diode 120.

Here, to transmit the light emitted by the light emitting diode 120 to the photodetector unit 220, the penetration hole LP is formed in the second pin electrode 232 and the second wiring line 235. The penetration hole LP may be an optical waveguide which transmits the light emitted from the light emitting diode 120 to the photodetector unit 220. For example, the light emitted from the light emitting diode 120 passes through the penetration hole LP to be incident on the photodetector unit 220 as represented by an arrow illustrated with a dotted line in FIG. 3. The penetration hole LP is disposed so as to overlap the photodetector unit 220 and passes through the second pin electrode 232 and the second wiring line 235. Further, the penetration hole LP is formed from the second pin electrode 232 and the second wiring line 235 to the second insulating layer 212 to be connected to the suction hole FP in the second insulating layer 212.

The reflection layer 233 may be disposed on a surface of the second pin electrode 232. The second pin electrode 232 is a hollow electrode in which the penetration hole LP is formed, and the reflection layer 233 may be disposed so as to cover an inner surface of the second pin electrode 232. Further, the reflection layer 233 may be disposed so as to cover an end portion of the second pin electrode 232. The reflection layer 233 may be disposed so as to cover a surface of the second pin electrode 232 to reflect light which travels to the penetration hole LP and to increase the amount of light incident on the photodetector unit 220. The reflection layer 233 may be formed by coating a surface of the second pin electrode 232 with a metal material having a high reflection efficiency, such as aluminum (Al).

The third insulating layer 213 is disposed on the electrode unit 230. The third insulating layer 213 may be disposed so as to cover the electrode unit 230. Specifically, the third insulating layer 213 may be disposed so as to cover the first wiring line 234 and the second wiring line 235 and may be disposed so as to enclose an outer surface of the first pin electrode 231 and an outer surface of the second pin electrode 232. The third insulating layer 213 may be formed of an insulating material with elasticity. For example, the third insulating layer 213 may be formed of a high elastic material, such as rubber or polyurethane.

The third insulating layer 213 may protrude from a surface of the first pin electrode 231 and from a surface of the second pin electrode 232 in a peripheral area PA of the first pin electrode 231 and the second pin electrode 232. The peripheral area PA is an area which encloses an outer surface of the first pin electrode 231 and an area which encloses an outer surface of the second pin electrode 232. For example, a part of the third insulating layer 213 disposed in the peripheral area PA may protrude from a surface of the first pin electrode 231 and from a surface of the second pin electrode 232 by a first length D1. The third insulating layer 213 protrudes from the first pin electrode 231 and the second pin electrode 232 to maintain airtightness when a suction force is applied to pick up and remove the defective light emitting diode 120. For example, when the probe card 200 is in contact with the light emitting diode array 100, a pressure is applied to compress the third insulating layer 213 to allow the first pin electrode 231 and the second pin electrode 232 to be in contact respectively with the first electrode 124 and the second electrode 125 of the light emitting diode 120. The compressed third insulating layer 213 may be attached to the light emitting diode 120 with a stronger force, and the airtightness between the light emitting diode 120 and the third insulating layer 213 may be improved.

Further, in the peripheral area PA, a part of the third insulating layer 213, which encloses the first pin electrode 231 and the second pin electrode 232, may disperse the force applied to the first pin electrode 231 and the second pin electrode 232 and reduce the potential damage on the first pin electrode 231 and the second pin electrode 232. When the probe card 200 and the light emitting diode array 100 are in contact with each other, the force may be dispersed to the third insulating layer 213 having an elastic force to minimize or suppress the potential defect of the first pin electrode 231 and/or the second pin electrode 232 being broken.

In another aspect, when the first pin electrode 231 and the second pin electrode 232 are in contact with the light emitting diode 120, to compress the third insulating layer 213 more easily, a width of the peripheral area PA, in which the third insulating layer 213 is located, may be configured to be equal to or smaller than a diameter of the first pin electrode 231. For example, the width of the third insulating layer 213 (corresponding to “D3” as shown in FIG. 2) of the peripheral area PA, which encloses the side surface of the first pin electrode 231 and the second pin electrode 232, may be at least equal to or smaller than the diameter of the first pin electrode 231 (corresponding to “D2” as shown in FIG. 2). If the width of the third insulating layer 213 of the peripheral area PA is formed to be larger than the diameter of the first pin electrode 231, it may be more difficult to compress the third insulating layer 213, and the respective contacts between the first pin electrode 231 and the second pin electrode 232 and the first electrode 124 and the second electrode 125 of the light emitting diode 120 may be more difficult. Accordingly, a width D3 of the peripheral area PA which encloses the first pin electrode 231 and the second pin electrode 232, that is, a width D3 of a part of the third insulating layer 213 may be limited to being no greater than the diameter of the first pin electrode 231 (i.e., D2) to compress the third insulating layer 213 more easily.

In this case, to compress the third insulating layer 213 more easily, the third insulating layer 213 may be formed to be relatively thin in the remaining area other than the peripheral area PA. For example, a thickness of a part of the third insulating layer 213 in the peripheral area PA may be larger than a thickness of the remaining part of the third insulating layer 213 in the remaining area.

To compress the third insulating layer 213 more easily so that the first pin electrode 231 and the second pin electrode 232 can come in contact respectively with the first electrode 124 and the second electrode 125 of the light emitting diode 120, the third insulating layer 213 may be configured with a material having a high stretching rate. For example, the third insulating layer 213 may be formed of a silicon-based material having a stretching rate of approximately 50% to 500%. For example, the third insulating layer 213 may have a stretching rate of approximately 106% or higher.

In another aspect, in the drawings (e.g., FIGS. 2 to 4), for the convenience of description, only one light emitting diode 120, one photodetector unit 220, and one electrode unit 230 are illustrated. However, a plurality of light emitting diodes 120 may be disposed on an array substrate 110, and a plurality of photodetector units 220 and a plurality of electrode units 230 corresponding to the plurality of light emitting diodes 120, respectively, may be disposed in the probe card 200. Accordingly, all of the plurality of light emitting diodes 120 on the array substrate 110 may be simultaneously inspected using the probe card 200 including the plurality of photodetector units 220 and the plurality of electrode units 230.

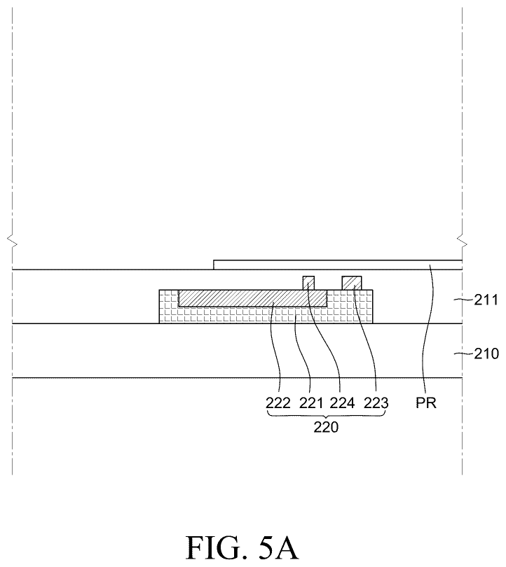

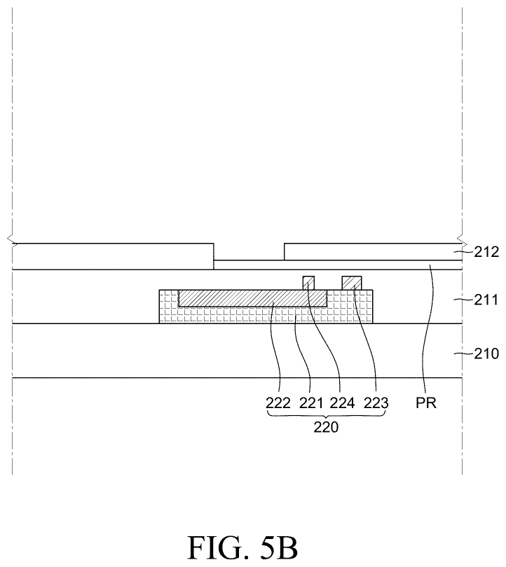

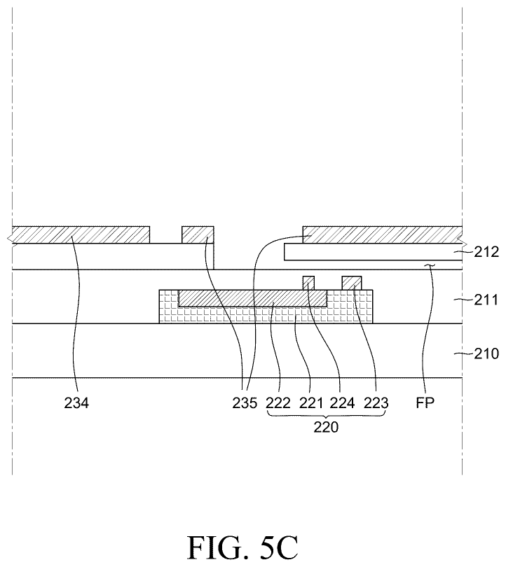

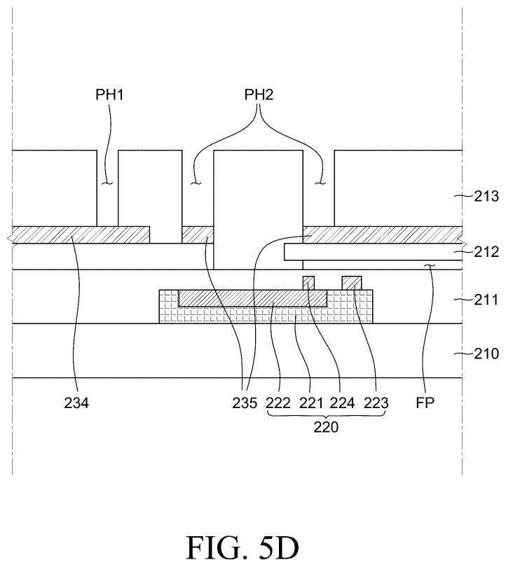

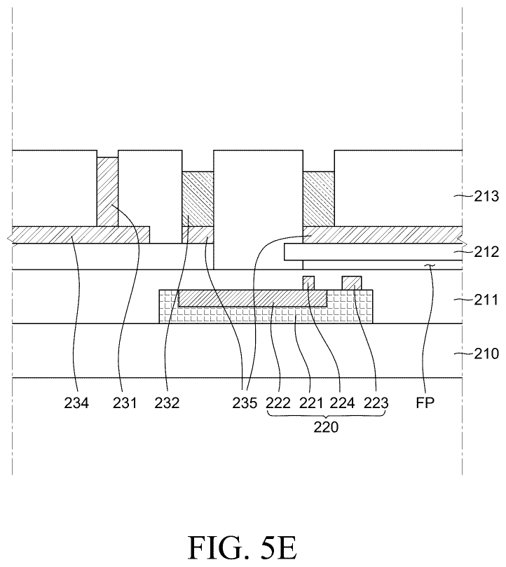

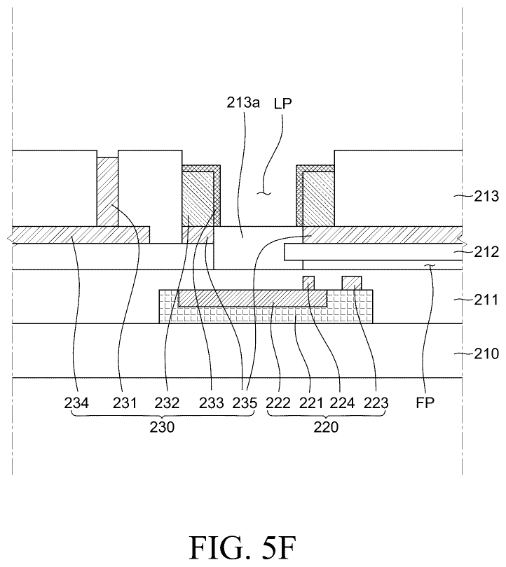

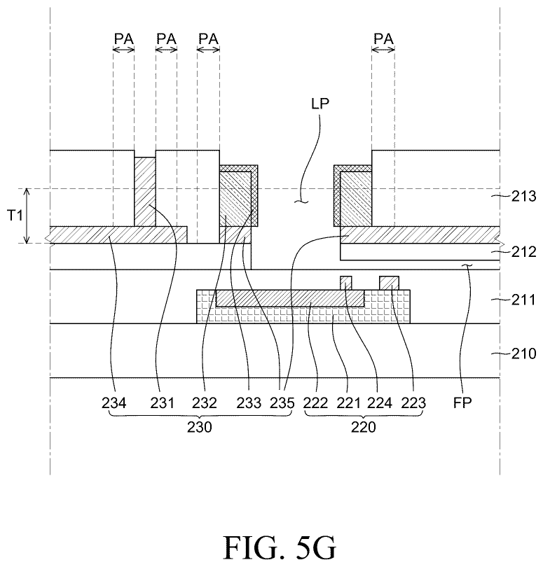

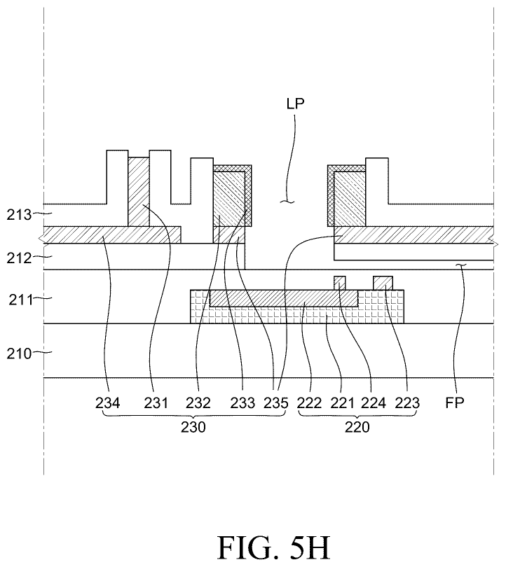

Hereinafter, a manufacturing method of a probe card 200 according to an example embodiment of the present disclosure will be described with reference to FIGS. 5A to 5H.

FIGS. 5A to 5H are process diagrams for explaining a manufacturing method of a probe card according to an example embodiment of the present disclosure.

As shown in FIG. 5A, the photodetector unit 220 is formed on the probe substrate 210. Specifically, the N-type semiconductor layer 221 may be formed on the probe substrate 210, and the P-type semiconductor layer 222 may be formed on the N-type semiconductor layer 221. The N-type electrode 223 may be formed on a top surface of the N-type semiconductor layer 221, and the P-type electrode 224 may be formed on a top surface of the P-type semiconductor layer 222.

Next, the first insulating layer 211 is formed on the probe substrate 210 and the photodetector unit 220, and the photoresist pattern PR is formed in a position corresponding to the suction hole FP and the penetration hole LP on the first insulating layer 211.

As illustrated in FIG. 5B, the second insulating layer 212 is formed on the photoresist pattern PR and the first insulating layer 211. At this time, the penetration hole LP may be formed in the second insulating layer 212 and the photoresist pattern PR may be exposed in the penetration hole LP.

As shown in FIG. 5C, the photoresist pattern PR is removed to form the suction hole FP. When the photoresist pattern PR is removed, the suction hole FP, which is an empty space, may be formed at the interface between the second insulating layer 212 and the first insulating layer 211. A part of the photoresist pattern PR is exposed through the penetration hole LP so that the photoresist pattern PR may be removed by applying a developer, etc., to the penetration hole LP.

Next, the first wiring line 234 and the second wiring line 235 of the electrode unit 230 are disposed on the second insulating layer 212. At this time, the penetration hole LP may also be formed in an end portion of the second wiring line 235 which overlaps the penetration hole LP of the second insulating layer 212.

As shown in FIG. 5D, the third insulating layer 213 is formed on the first wiring line 234 and the second wiring line 235, and the first pin hole PH1 and the second pin hole PH2 are formed in the third insulating layer 213. The first pin hole PH1 may be formed in the position of the first pin electrode 231 to have the same shape as the first pin electrode 231, and the second pin hole PH2 may be formed in the position of the second pin electrode 232 to have the same shape as the second pin electrode 232.

As illustrated in FIG. 5E, the first pin electrode 231 and the second pin electrode 232 are formed. The first pin electrode 231 and the second pin electrode 232 may be formed respectively in the first pin hole PH1 and the second pin hole PH2 by performing a plating process.

As illustrated in FIG. 5F, a part of the third insulating layer 213 located on the inner surface of the second pin electrode 232 is removed, and the reflection layer 233 is formed on the inner and upper surfaces of the second pin electrode 232. A part of the third insulating layer 213 corresponding to the penetration hole LP is removed to expose the inner surface of the second pin electrode 232. At this time, at a part of the penetration hole LP where the reflection layer 233 is not formed, for example, on a surface of the second wiring line 235, a surface of the first insulating layer 211, and a surface of the second insulating layer 212, a residual film 213a of the third insulating layer 213 remains so that the reflection layer 233 is not formed. The reflection layer 233 may be coated on the surface of the second pin electrode 232 exposed from the third insulating layer 213.

As shown in FIGS. 5G and 5H, the residual film 213a of the third insulating layer 213 located in the penetration hole LP is removed, and the third insulating layer 213 in the remaining area other than the peripheral area PA is partially etched.

The residual film 213a of the third insulating layer 213 located in the penetration hole LP area may be removed so that the penetration hole LP and the suction hole FP may be connected to each other.

A thickness of the remaining part of the third insulating layer 213 located in the remaining area other than the peripheral area PA may be etched to a first thickness T1. The first thickness T1 is smaller than a thickness of the third insulating layer 213 located in the peripheral area PA.

A part of the third insulating layer 213 located in the peripheral area PA of the first pin electrode 231 and the peripheral area PA of the second pin electrode 232 may also be etched in consideration of height of the upper surfaces of the first pin electrode 231 and the second pin electrode 232. For example, in the peripheral area PA, the third insulating layer 213 of the peripheral area PA may be partially etched so that the third insulating layer 213 protrudes respectively from the upper surfaces of the first pin electrode 231 and the second pin electrode 232 by the first length D1.

Accordingly, in the probe card 200 according to an example embodiment of the present disclosure, the plurality of photodetector units 220 and the plurality of electrode units 230 are formed to simultaneously inspect the electrical characteristics and the optical characteristics of the plurality of light emitting diodes 120. The photodetector units 220 sense the light emitted respectively from the light emitting diodes 120 to inspect the optical characteristics, and the electrode units 230 inspect the electrical characteristics respectively from currents flowing through the light emitting diodes 120. Therefore, a normal light emitting diode 120 satisfying both the optical characteristic and the electrical characteristic may be accurately detected. Further, in the probe card 200, the plurality of electrode units 230 and the plurality of photodetector units 220 may be disposed to simultaneously inspect all of the plurality of light emitting diodes 120 in the light emitting diode array 100. Accordingly, the plurality of photodetector units 220 and the plurality of electrode units 230 may be disposed in the probe card 200 together to simultaneously inspect various characteristics of the plurality of light emitting diodes 120, thus simplifying the inspection process of the light emitting diode 120 and shortening the inspection time.

In the probe card 200 according to an example embodiment of the present disclosure, the penetration hole LP and the reflection layer 233 may be formed to allow the photodetector unit 220 to sense light from the light emitting diode 120 more easily and efficiently. The photodetector unit 220 may be disposed on the emission layer 122 of the light emitting diode 120, and the penetration hole LP may be formed in the second pin electrode 232 which overlaps the emission layer 122. As the second pin electrode 232 is configured as a hollow pin electrode including the penetration hole LP, the second pin electrode 232 does not interrupt the light transmitted toward the photodetector unit 220, and the light emitted from the emission layer 122 may be incident on the photodetector unit 220 by passing through the penetration hole LP. Further, the reflection layer 233 is formed inside the second pin electrode 232 to reflect the light so as to allow more of the light from the light emitting diode 120 to be incident on the photodetector unit 220. Accordingly, an amount of light sufficient to inspect the light emitting diode 120 may be ensured, and specifically, an emission failure of a light emitting diode 120 may be more easily detected in a low current and low grayscale band.

In the probe card 200 according to an example embodiment of the present disclosure, when a defective light emitting diode 120 is detected, the suction hole FP can be used to apply a suction force to pick up the defective light emitting diode 120 for removal. After the inspection of the light emitting diode array 100 is completed, a vacuum suction equipment may be connected to the suction hole FP located on the defective light emitting diode 120 to fix the defective light emitting diode 120 to the second pin electrode 232 by applying a suction force. Accordingly, the defective light emitting diode 120, among the plurality of light emitting diodes 120, may be accurately picked up and removed by the vacuum suction method using the suction hole FP.

In the probe card 200 according to an example embodiment of the present disclosure, the third insulating layer 213 in the peripheral area PA protrudes from the first pin electrode 231 and the second pin electrode 232 to maintain the airtightness while the defective light emitting diode 120 is picked up with a suction force. The third insulating layer 213 may be an insulating layer with elasticity and may be compressed by pressure. When the probe card 200 is in contact with the light emitting diode array 100, a pressure can be applied to compress the protruding third insulating layer 213 to allow the first pin electrode 231 and the second pin electrode 232 to be in contact respectively with the first electrode 124 and the second electrode 125 of the light emitting diode 120. Accordingly, the third insulating layer 213 enclosing the second pin electrode 232, in which the penetration hole LP is located, may be pressed to the light emitting diode 120 by the pressure of the probe card 200, and the airtightness of the penetration hole LP and the suction hole FP may be more easily maintained.

In the probe card 200 according to an example embodiment of the present disclosure, the third insulating layer 213 is formed on outer surfaces of the first pin electrode 231 and the second pin electrode 232 to disperse the force to be applied to the first pin electrode 231 and the second pin electrode 232. The first pin electrode 231 and the second pin electrode 232 formed of metal have a diameter of a micro-size and thus may be vulnerable to the external impact and be easily damaged. In contrast, the third insulating layer 213 having elasticity can be more flexibly deformed and can disperse and relieve the force applied thereto. Accordingly, the third insulating layer 213 may protect the first pin electrode 231 and the second pin electrode 232 from the applied pressure during the contact between the probe card 200 and the light emitting diode array 100 or from an external impact, thus minimizing or suppressing damages to the first pin electrode 231 and the second pin electrode 232.

Example embodiments of the present disclosure can also be described as follows:

According to an aspect of the present disclosure, a probe card includes a probe substrate, a photodetector unit on the probe substrate, an electrode unit on the photodetector unit and including a first pin electrode and a second pin electrode, a penetration hole through the second pin electrode, the penetration hole overlapping the photodetector unit.

The photodetector unit may include an N-type semiconductor layer on the probe substrate, a P-type semiconductor layer on the N-type semiconductor layer, an N-type electrode connected to the N-type semiconductor layer, and a P-type electrode connected to the P-type semiconductor layer.

The electrode unit may further include a first wiring line connected to the first pin electrode, a second wiring line connected to the second pin electrode, and a reflection layer on an inner surface of the second pin electrode facing the penetration hole. The penetration hole may further extend through the second wiring line.

The first pin electrode may have a pin shape, and the second pin electrode may have a hollow pin shape with a hollow center forming a part of the penetration hole.

The probe card may further include a first insulating layer covering the photodetector unit, a second insulating layer on the first insulating layer, and a third insulating layer on the second insulating layer and covering at least a part of the electrode unit. The third insulating layer may include an insulating material having elasticity.

The third insulating layer may enclose an outer surface of the first pin electrode and an outer surface of the second pin electrode.

In a peripheral area enclosing the outer surface of the first pin electrode and the outer surface of the second pin electrode, the third insulating layer may protrude from an end of the first pin electrode and from an end of the second pin electrode.

A thickness of a part of the third insulating layer disposed in the peripheral area is larger than a thickness of another part of the third insulating layer disposed in another area other than the peripheral area.

The probe card may further include a suction hole along an interface between the first insulating layer and the second insulating layer, and the penetration hole may further extend through the second insulating layer and be connected with the suction hole.

According to another aspect of the present disclosure, a probe card for inspecting a light emitting diode array includes a probe substrate, a plurality of photodetector units on the probe substrate, and a plurality of electrode units, each on a corresponding one of the photodetector units and including a first pin electrode and a second pin electrode. The second pin electrode may include a hollow center overlapping the corresponding one of the photodetector units.

Each of the photodetector units may include an N-type semiconductor layer and a P-type semiconductor layer stacked on each other on the probe substrate, an N-type electrode connected to the N-type semiconductor layer, and a P-type electrode connected to the P-type semiconductor layer.

Each of the electrode units may further include a first wiring line connected to the first pin electrode, a second wiring line connected to the second pin electrode, and a reflection layer on an inner surface of the second pin electrode facing the hollow center.

The first pin electrode may have a pin shape, the second pin electrode may have a hollow pin shape with the hollow center forming a part of a penetration hole overlapping the corresponding one of the photodetector units, and the penetration hole may extend through the second pin electrode and the second wiring line.

The probe card may further include a first insulating layer covering the photodetector units, a second insulating layer on the first insulating layer, and a third insulating layer on the second insulating layer and covering at least a part of the electrode units. The third insulating layer may include an insulating material having elasticity.

The third insulating layer may enclose an outer surface of the first pin electrode and an outer surface of the second pin electrode in a peripheral area. The third insulating layer in the peripheral area may protrude from an end of the first pin electrode and from an end of the second pin electrode. The third insulating layer may have a larger thickness in the peripheral area than in another area outside the peripheral area, or may have a width in the peripheral area that is smaller or equal to a width of the first pin electrode.

The probe card may further include a suction hole along an interface between the first insulating layer and the second insulating layer, and the penetration hole may further extend through the second insulating layer and be connected with the suction hole.

According to yet another aspect of the present disclosure, a method for inspecting a light emitting diode array including a plurality of light emitting diodes on a array substrate includes contacting the plurality of light emitting diodes respectively with the electrode units of an above-described probe card; inspecting an optical characteristic and an electrical characteristic of each of the plurality of light emitting diodes respectively with an adjacent one of the photodetector units and an adjacent one of the electrode units of the probe card to determine if any of the plurality of light emitting diodes is defective; and if a light emitting diode, among the plurality of light emitting diodes, is determined to be defective, picking up the defective light emitting diode with the probe card.

Each of the plurality of light emitting diodes may include a first electrode and a second electrode. The contacting of the plurality of light emitting diodes may includes positioning the probe card so that each of the plurality of light emitting diodes overlaps the adjacent one of the photodetector units and the adjacent one of the electrode units, and contacting the first electrode and second electrode of each of the plurality of light emitting diodes respectively with the first pin electrode and the second pin electrode of the adjacent one of the electrode units of the probe card.

The inspecting of the optical characteristic and the electrical characteristic may include simultaneously applying a voltage to the first electrode and the second electrode of each of the plurality of light emitting diodes respectively through the first pin electrode and the second pin electrode of the adjacent one of the electrode units, and simultaneously detecting light emitted by each of the plurality of light emitting diodes with the adjacent one of the photodetector units. The second pin electrode of the adjacent one of the electrode units may be positioned so that the light emitted by each of the plurality of light emitting diodes is transmitted through the hollow center of the second pin electrode to be incident on the adjacent one of the photodetector units.

The probe card may further include a first insulating layer on the photodetector units, a second insulating layer on the first insulating layer, and a suction hole between the first insulating layer and the second insulating layer and connected to the hollow center of the second pin electrode. The picking up of the defective light emitting diode may include vacuum-sucking the defective light emitting diode to the second pin electrode through the suction hole and the hollow center of the second pin electrode.

Although example embodiments of the present disclosure have been described in detail above with reference to the accompanying drawings, the present disclosure is not limited thereto and may be embodied in many different forms without departing from the technical concept of the present disclosure. Therefore, the example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A probe card, comprising:
a probe substrate;
a photodetector unit on the probe substrate;
an electrode unit on the photodetector unit and including a first pin electrode and a second pin electrode; and
a penetration hole through the second pin electrode, the penetration hole overlapping the photodetector unit.

2. The probe card of claim 1, wherein the photodetector unit includes:
an N-type semiconductor layer on the probe substrate;
a P-type semiconductor layer on the N-type semiconductor layer;
an N-type electrode connected to the N-type semiconductor layer; and
a P-type electrode connected to the P-type semiconductor layer.

3. The probe card of claim 1, wherein the electrode unit further includes:
a first wiring line connected to the first pin electrode;
a second wiring line connected to the second pin electrode; and
a reflection layer on an inner surface of the second pin electrode facing the penetration hole, and
wherein the penetration hole further extends through the second wiring line.

4. The probe card of claim 3, wherein the first pin electrode has a pin shape, and the second pin electrode has a hollow pin shape with a hollow center forming a part of the penetration hole.

5. The probe card of claim 3, further comprising:
a first insulating layer covering the photodetector unit;
a second insulating layer on the first insulating layer; and
a third insulating layer on the second insulating layer and covering at least a part of the electrode unit, and
wherein the third insulating layer includes an insulating material having elasticity.

6. The probe card of claim 5, wherein the third insulating layer encloses an outer surface of the first pin electrode and an outer surface of the second pin electrode.

7. The probe card of claim 6, wherein in a peripheral area enclosing the outer surface of the first pin electrode and the outer surface of the second pin electrode, the third insulating layer protrudes from an end of the first pin electrode and from an end of the second pin electrode.

8. The probe card of claim 7, wherein a thickness of a part of the third insulating layer disposed in the peripheral area is larger than a thickness of another part of the third insulating layer disposed in another area other than the peripheral area.

9. The probe card of claim 5, further comprising:
a suction hole along an interface between the first insulating layer and the second insulating layer,
wherein the penetration hole further extends through the second insulating layer and is connected with the suction hole.

10. A probe card for inspecting a light emitting diode array, the probe card comprising:
a probe substrate;
a plurality of photodetector units on the probe substrate; and
a plurality of electrode units, each on a corresponding one of the photodetector units and including a first pin electrode and a second pin electrode,
wherein the second pin electrode includes a hollow center overlapping the corresponding one of the photodetector units.

11. The probe card of claim 10, wherein each of the photodetector units includes:
an N-type semiconductor layer and a P-type semiconductor layer stacked on each other on the probe substrate;
an N-type electrode connected to the N-type semiconductor layer; and
a P-type electrode connected to the P-type semiconductor layer.

12. The probe card of claim 10, wherein each of the electrode units further includes:
a first wiring line connected to the first pin electrode;
a second wiring line connected to the second pin electrode; and
a reflection layer on an inner surface of the second pin electrode facing the hollow center.

13. The probe card of claim 12, wherein:
the first pin electrode has a pin shape;
the second pin electrode has a hollow pin shape with the hollow center forming a part of a penetration hole overlapping the corresponding one of the photodetector units; and
the penetration hole extends through the second pin electrode and the second wiring line.

14. The probe card of claim 13, further comprising:
a first insulating layer covering the photodetector units;
a second insulating layer on the first insulating layer; and
a third insulating layer on the second insulating layer and covering at least a part of the electrode units, and
wherein the third insulating layer includes an insulating material having elasticity.

15. The probe card of claim 14, wherein:
the third insulating layer encloses an outer surface of the first pin electrode and an outer surface of the second pin electrode in a peripheral area;
the third insulating layer in the peripheral area protrudes from an end of the first pin electrode and from an end of the second pin electrode; and
the third insulating layer has a larger thickness in the peripheral area than in another area outside the peripheral area, or has a width in the peripheral area that is smaller or equal to a width of the first pin electrode.

16. The probe card of claim 14, further comprising:
a suction hole along an interface between the first insulating layer and the second insulating layer,
wherein the penetration hole further extends through the second insulating layer and is connected with the suction hole.

17. A method for inspecting a light emitting diode array including a plurality of light emitting diodes on a array substrate, the method comprising:
contacting the plurality of light emitting diodes respectively with the electrode units of the probe card of claim 10;
inspecting an optical characteristic and an electrical characteristic of each of the plurality of light emitting diodes respectively with an adjacent one of the photodetector units and an adjacent one of the electrode units of the probe card to determine if any of the plurality of light emitting diodes is defective; and
if a light emitting diode, among the plurality of light emitting diodes, is determined to be defective, picking up the defective light emitting diode with the probe card.

18. The method of claim 17, wherein:
each of the plurality of light emitting diodes includes a first electrode and a second electrode; and
the contacting of the plurality of light emitting diodes includes:
positioning the probe card so that each of the plurality of light emitting diodes overlaps the adjacent one of the photodetector units and the adjacent one of the electrode units; and
contacting the first electrode and second electrode of each of the plurality of light emitting diodes respectively with the first pin electrode and the second pin electrode of the adjacent one of the electrode units of the probe card.

19. The method of claim 18, wherein the inspecting of the optical characteristic and the electrical characteristic includes:
simultaneously applying a voltage to the first electrode and the second electrode of each of the plurality of light emitting diodes respectively through the first pin electrode and the second pin electrode of the adjacent one of the electrode units; and
simultaneously detecting light emitted by each of the plurality of light emitting diodes with the adjacent one of the photodetector units, and
wherein the second pin electrode of the adjacent one of the electrode units is positioned so that the light emitted by each of the plurality of light emitting diodes is transmitted through the hollow center of the second pin electrode to be incident on the adjacent one of the photodetector units.

20. The method of claim 18, wherein the probe card further includes:
a first insulating layer on the photodetector units;
a second insulating layer on the first insulating layer; and
a suction hole between the first insulating layer and the second insulating layer and connected to the hollow center of the second pin electrode, and
wherein the picking up of the defective light emitting diode includes vacuum-sucking the defective light emitting diode to the second pin electrode through the suction hole and the hollow center of the second pin electrode.
